(19) United States
(12) Patent Application Publication
(10) Pub. No.: US 2026/0369333 A1
(43) Pub. Date: Nov. 19, 2026

(54) IMPLEMENTING DATA CACHING TO REDUCE LATENCY ASSOCIATED WITH PERFORMING WRITE OPERATIONS ON MEMORY DEVICES IN A MEMORY SUB-SYSTEM

(71) Applicant: Micron Technology, Inc., Boise, ID (US)

(72) Inventors: Chong Giap Chiew, San Jose, CA (US); Sean Brasfield, Boise, ID (US); Tawalin Opastrakoon, Boise, ID (US)

(21) Appl. No.: 19/207,117

(22) Filed: May 13, 2025

(51) Int. Cl. G11C 16/34; G11C 16/10; G11C 16/16

(52) U.S. Cl. CPC G11C 16/3445; G11C 16/102; G11C 16/16

(57) ABSTRACT

A write command for corresponding data to be written to a block associated with a blockstripe of a plurality of blockstripes spanning a plurality of memory devices is received. An erase algorithm is initiated on the block in response to receiving the write command. The erase algorithm comprises at least a first operation, a second operation, and a third operation performed by control logic of the memory device. The data to be written to the block is loaded into a cache memory portion of a memory device associated with the block in parallel with execution of the second operation by the control logic of the memory device. The data is written to the block based on completion of the first operation, the second operation, and the third operation. The data is read from the cache memory portion of the memory device associated with the block in order to write the data to the block.

### TECHNICAL FIELD

Embodiments of the disclosure relate generally to memory sub-systems, and more specifically, relate to implementing data caching to reduce latency associated with performing write operations on memory devices in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIG. 2 illustrates a flow diagram of an example method of implementing data caching to reduce latency associated with performing write operations on memory devices in a memory sub-system, in accordance with some embodiments of the present disclosure.

FIG. 3 illustrates a flow diagram of an example method of implementing data caching to reduce latency associated with performing write operations on memory devices in a memory sub-system, in accordance with some embodiments of the present disclosure.

FIG. 4 illustrates an example method for implementing data caching to reduce latency associated with performing write operations on memory devices in a memory sub-system, in accordance with some embodiments of the present disclosure.

FIG. 5 illustrates a block diagram of an example computer system in which embodiments of the present disclosure may operate.

### DETAILED DESCRIPTION

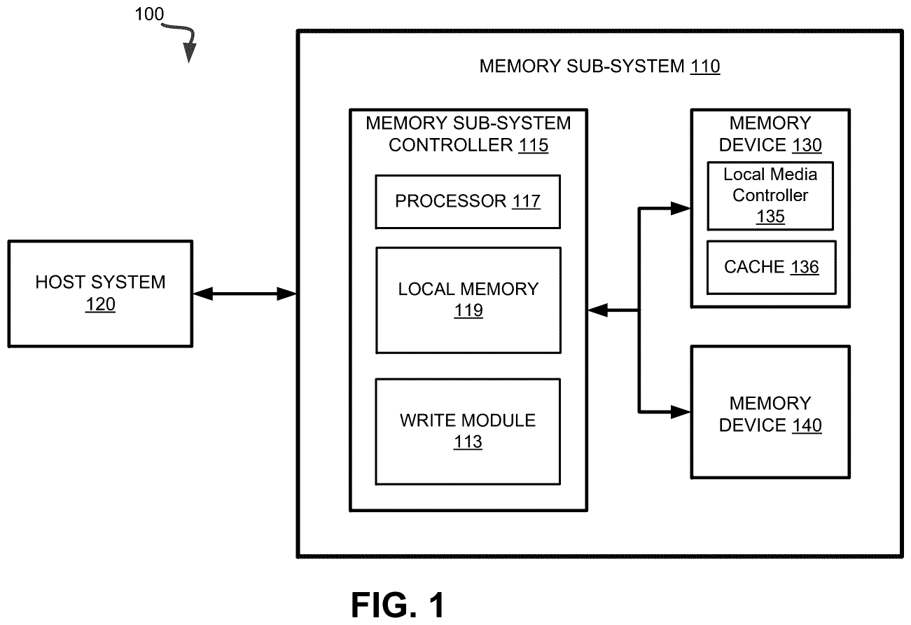

Aspects of the present disclosure are directed to implementing data caching to reduce latency associated with performing write operations on memory devices in a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory sub-system controller (“controller”) can execute an erase algorithm to erase specific blocks located on a memory device. In some instances, the controller executes the erase algorithm on a block without receiving a command from a host system (“host”) to perform a memory access operation on the block. As such, upon receipt of a command to program (i.e., write) data to a logical block address (LBA) associated with the block, the controller can load the data into cache memory associated with the memory device and program consecutive pages of the block. In some instances, the controller can execute the erase algorithm based on receiving a command to write data to a specific LBA. The command can indicate the block to be programmed and the data to be written to the block. The execution of the erase algorithm can return the block to an unwritten state in instances where the block was previously programmed (e.g., erase on demand), for example. Further, the execution of the erase algorithm can ensure that the block remains in an unwritten state in instances where the block was not previously programmed, for example. Executing the erase algorithm on the block can include performing a plurality of operations on the block.

The controller can perform a first operation on the memory device that is associated with the block. During the first operation, the controller can apply a select gate status check voltage to a select gate to determine whether the select gate voltage threshold are at an acceptable level. A select gate can be used to control a string of memory cells, including one or more cells associated with the block to which the data is to be written. An operational state of the select gate can change from, for example, a first operational state (e.g., an “OFF” state) to a second operational state (e.g., an “ON” state) when a control signal voltage is applied to a control line, such as the wordline to which the select gate is connected. When the select gate is in the first operational state (e.g., the “OFF” state), the select gate prevents the corresponding string of memory cells from connecting to the bitline. However, when the select gate is in the second operational state (e.g., the “ON” state), the select gate can enable the memory cells in the corresponding string to connect to the bitline. As such, when the select gate is in the second operational state, the select gate can cause data to be written to and/or read from the specific memory cells that are connected to the bitline.

In some instances, the functionality of the select gate can be disturbed based on the applications that the memory sub-system supports. The controller can apply the select gate status check voltage to the select gate to determine whether the select gate can enable the string of memory cells to connect to the bitline. Specifically, the controller can apply the select gate status check voltage to the wordline to which the select gate is connected to change the operational state of the select gate to the “ON” state. By applying the select gate status check voltage to the select gate, the controller can perform a sense read on the select gate to determine the state of the select gate (e.g., whether the select gate is in the “ON” state). Performing the sense read on the select gate can cause sense data that is associated with the sense read to buffer within the cache memory associated with the memory device. As such, the memory device is occupied during the execution of the first operation, during which time the NAND data cache is not available.

Based on determining that the operational state of the select gate does not change (e.g., to the “ON” state) when the select gate status check voltage is applied, the controller can terminate the execution of the erase algorithm. Alternatively, based on determining that the operational state of the select gate changes (e.g., to the “ON” state) when the select gate status check voltage is applied, the controller can perform a second operation on the block.

The controller can perform the second operation to determine the voltage level distribution of the cells associated with the block. The processing device can also determine an erase voltage level (e.g., VERA) to be applied to the cells associated with the block. The cells that are associated with the block can experience different portions of a voltage level distribution, such as a low voltage level portion of the voltage level distribution or a high voltage level portion of the voltage level distribution. For each cell that is associated with the low voltage level portion of the voltage level distribution, the processing device can increase the voltage level associated with the cell such that the cell experiences the high voltage level portion of the voltage level distribution (i.e., the controller compacts the voltage level of the cells toward the high voltage level portion of the voltage level distribution to minimize the range of voltage level distribution). The processing device can apply the VERA to the block and perform the third operation, causing the cells in the block to be erased. In some instances, applying the VERA to the block can include applying a high voltage signal to a source line and a bitline associated with the block (e.g., to expel electrons from the cells of the block).

During the third operation, the controller can erase the block and perform an erase verify (e.g., EV) operation on the cells associated with the block. Performing the erase verify operation can include performing a read sensing algorithm on the block to determine whether the block is in an acceptable erased state. In some instances, the controller can perform an erase verify on the cells associated with the block to determine the voltage level distribution of the cells after the VERA is applied. The controller can determine whether the voltage levels of the cells are within a target erase voltage distribution. Based on determining that the voltage levels of the cells are not within the target erase voltage distribution (e.g., do not satisfy the EV operation voltage level requirement), the controller can repeat the third operations. The controller can repeat the third operations until, for example, the controller determines that block is erased. Based on determining that the voltage levels of the cells are within the target erase voltage distribution (e.g., satisfy the EV operation voltage level requirement), the controller can terminate the erase algorithm.

When the erase algorithm is terminated, the controller can initiate a data loading sequence to load the data to be written to the block into the cache memory associated with the memory device. Specifically, the controller can load data to be written to a first page of the block into the cache memory. When the data to be written to the first page of the block is loaded into the cache memory, the controller can read the data from the cache memory and write the data to the first page of the block. The controller can load data to be written a subsequent page of the block into the cache memory. The controller can read the data from the cache memory and write the data to the subsequent page of the block. The controller can continue the data loading sequence and programming consecutive pages of the block until, for example, all of the data indicated in the write command is programmed to the memory device. However, performing an erase operation prior to programming the first page of the block can increase the latency. Further, an amount of time needed for each operation to complete can vary, thereby introducing additional latency associated with executing the write command. The additional latency associated with the execution of the erase algorithm and the write command (e.g., erase on demand) can reduce the reliability of the memory device and impact the performance of the memory device.

Aspects of the present disclosure address the above and other deficiencies by implementing data caching to reduce latency associated with performing a block erase operation prior to immediate write operations (e.g., erase on demand) on memory devices. A memory sub-system controller (“controller”) can execute an erase algorithm on a block located on a memory device. In some instances, the controller can execute the erase algorithm without receiving a command from a host system (“host”) (e.g., a command to perform a memory access operation on the block). In such instances, the controller executes the erase algorithm on the block to prepare the block for a memory access operation, memory management operation, etc. that can be performed at a later time. For example, upon receipt of a command to program (i.e., write) data to a logical block address (LBA) associated with the block, the controller can proceed with performing the write command since the block was previously erased, thereby reducing the latency associated with writing the data to the block. Additionally or alternatively, the controller can execute the erase algorithm based on receiving a command from the host to write data to a specific LBA. The erase algorithm can include a plurality of operations, which include at least the first, second, and third operations that are described above.

Based on determining that a block is to be erased, the controller can perform the first operation. Upon completion of the first operation, the controller can, in parallel, perform the second operation and initiate a data loading sequence to load a portion of the data to be written to the block into the cache memory associated with the memory device. Specifically, the controller can load data to be written to a first page of the block into the cache memory. When the second operation is complete, the controller can perform the third operation. In some instances, the controller can iteratively perform the second and third operations (e.g., until the block is erased, until a voltage level of each cell that is associated with the block is within a target erase voltage distribution). Based on determining that the voltage level of each cell that is associated with the block is within the target erase voltage distribution, the controller can terminate the erase algorithm. The controller can read the data from the cache memory and write the data to the first page of the block. The controller can load a load data to be written to a subsequent page of the block into the cache memory. The controller can read the data from the cache memory and write the data to the subsequent page of the block. The controller can continue this process until, for example, the totality of the data received from the host is written to the block.

Advantages of the present disclosure include, but are not limited to, reducing the latency associated with executing an erase algorithm on a block to which data is to be written by performing aspects of the erase algorithm in parallel. Advantages of the present disclosure further include reducing the latency associated with executing a write command on the block by performing aspects of the erase algorithm and loading a portion of the data to be written to pages of the block into cache memory in parallel. Advantages of the present disclosure further include reducing the latency associated with executing the write command by reading data from the cache memory and writing the data to consecutive pages of the block upon completion of the erase algorithm, thereby increasing the reliability and efficiency of the memory device. Advantages of the present disclosure further include executing the erase algorithm to maintain the block in an erased state, thereby reducing the latency associated with performing a write command on the block.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and at least one of an MLC portion, a TLC portion, a QLC portion, or a PLC portion of memory cells. In some instances, each of the memory devices 130 can include a cache memory portion (e.g., cache 136), which can be, for example, SRAM or TCM. In some instances, the cache 136 can correspond to an SLC portion of the memory device 130. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a write module 113 that can perform the write commands described herein. In some embodiments, the memory sub-system controller 115 includes at least a portion of the write module 113. In some embodiments, the write module 113 is part of the host system 120, an application, or an operating system. In other embodiments, local media controller 135 includes at least a portion of the write module 113 and is configured to perform the functionality described herein.

In some instances, the write module 113 can be executed by a processing device associated with memory sub-system 110. In some instances, the write module 113 can receive from the host device (e.g., a device that includes host system 120) a command to erase a block associated with a memory device, such as one of memory devices 130, 140. In some instances, the write module 113 can receive from the host device a command to write data to a block associated with the memory device. Based on receiving either the erase command and/or the write command, the write module 113 can send an erase command to memory device 130. Upon receiving an erase command, local media controller 135 then initiate an erase algorithm on the block. The local media controller 135 can initiate a first operation on the memory device that is associated with the block. Upon completion of the first operation, the local media controller 135 can, in parallel, perform a second operation while the write module 113 loads data to be written to a first page of the block into cache memory of the memory device 130. The local media controller 135 can iteratively perform the second and third operations, for example, until the block is erased (i.e., until a voltage level of each cell that is associated with the block is within a target erase voltage distribution). Based on determining that the requirements of the second and third operations are satisfied, the local media controller 135 can terminate the erase algorithm. The local media controller 135 can execute a program algorithm and program the data from the cache memory to the first page of the block. The write module 113 can load data to be written to a subsequent page of the block into the cache memory. The local media controller 135 can execute a program algorithm and program the data from the cache memory to the subsequent page of the block. The write module 113 can iteratively load portions of the data to be programmed to pages of the block to the cache memory and local media controller 135 program data from the cache memory to corresponding pages of the block until, for example, the totality of the data indicated in the write command is programmed to the block. Further details regarding the operations of the write module 113 and local media controller 135 are described below.

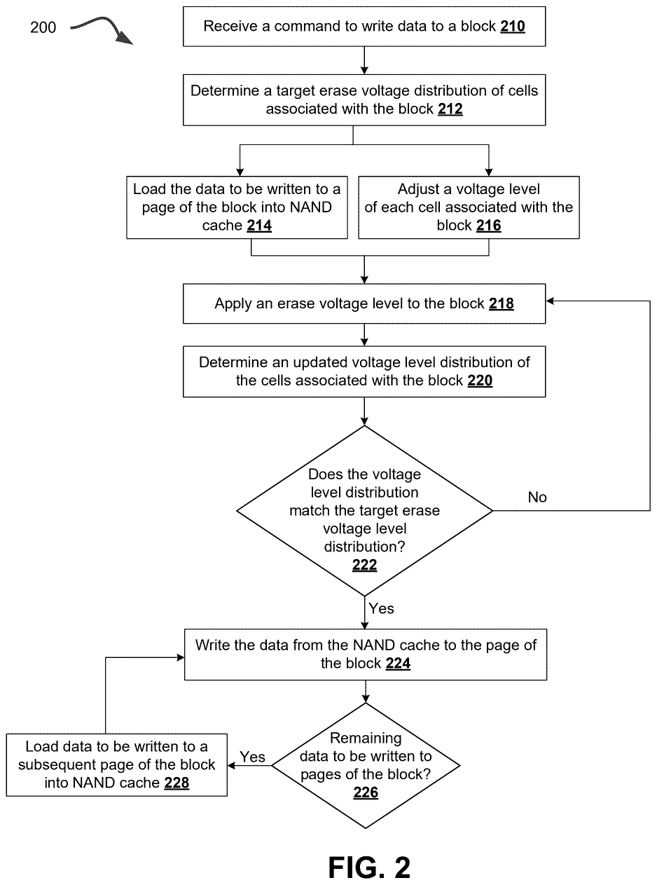

FIG. 2 illustrates a flow diagram of an example method of implementing data caching to reduce latency associated with performing write operations on memory devices, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the write module 113 and local media controller 135 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

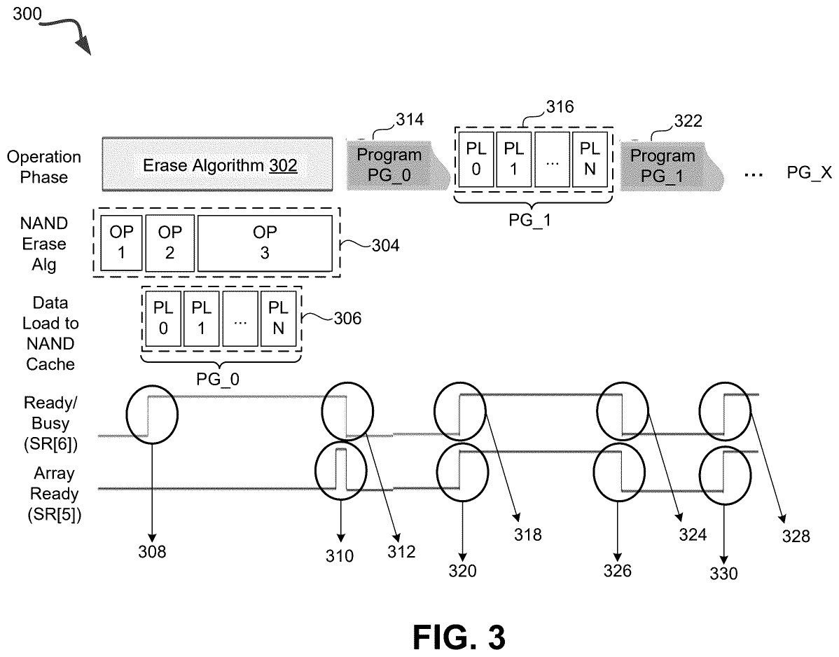

At operation 210, the processing logic (e.g., the write module 113) can receive, from a host device (e.g., a host device associated with the host system 120 of computing system 100), a command to write data to a block associated with a memory device (e.g., memory devices 130, 140 of computing system 100). The write command can indicate the block to be programmed and the data to be written to the block. Upon receipt of the write command, the processing logic can initiate an erase algorithm on the block to which the data is to be written, if the block is not already in an erased state. Executing the erase algorithm on the block can include performing a plurality of operations on the memory devices associated with the block and on the block. FIG. 3 illustrates a flow diagram of an example method of implementing data caching to reduce latency associated with performing write operations on memory devices, in accordance with some embodiments of the present disclosure. As illustrated in FIG. 3, control logic of the memory device (e.g., the local media controller 135) can execute erase algorithm 302 upon receipt of the erase command from the processing logic (e.g., the write module 113). The erase algorithm 302 can include the plurality of operations 304, which can include at least a first operation (e.g., OP 1), a second operation (e.g., OP 2), and a third operation (e.g., OP 3).

The control logic (e.g., the local media controller 135) can perform the first operation (e.g., OP 1) on the memory device that is associated with the block to which the data is to be written. Specifically, the control logic (e.g., the local media controller 135) can perform the first operation on a select gate that controls a string of memory cells, including one or more memory cells associated with the block to which the data is to be written. The one or more memory cells associated with the block can be arranged along a number of separate wordlines. The block can include a number of sub-blocks, where each sub-block is defined by an associated pillar (e.g., a vertical conductive trace) extending between a shared bitline at one end and a source at the other end. Since the sub-blocks can be accessed separately (e.g., to perform program or read operations), the block can include a structure to selectively enable the pillar associated with a certain sub-block, while disabling the pillars associated with other sub-blocks. This structure can include one or more select gate devices positioned at either or both ends of each pillar. Depending on a control signal applied, these select gate devices can either enable or disable the conduction of signals through the pillars.

In a first operational state (e.g., the “OFF” state), the select gate prevents the corresponding string of memory cells from connecting to the bitline. However, in a second operational state (e.g., the “ON” state), the select gate can enable the memory cells in the corresponding string to connect to the bitline. The processing device can perform the first operation to determine whether the operational state of the select gate changes to the “ON” state when the control signal voltage is applied to the select gate. To do so, the processing device can apply a select gate status check voltage to the select gate to perform a sense read on the select gate. During the execution of the first operation, sense data that is associated with the sense read can buffer within the cache memory of the memory device. As such, the memory device is occupied during the execution of the first operation. During the execution of the first operation, a status register that is associated with the memory device can experience a first state (e.g., a low state). The low state indicates that the memory device is occupied (e.g., the memory device is not prepared to receive the data to be written to the block, the data is being written to the memory device, etc.).

Based on determining that the operational state of the select gate does not change to the “ON” state when the select gate status check voltage is applied to the select gate, the processing device can terminate the erase algorithm. Based on determining that the operational state of the select gate changes to the “ON” state when the select gate status check voltage is applied to the select gate, the processing device can terminate the first operation and perform the second operation (e.g., OP 2). Upon termination of the first operation, the status register that is associated with the memory device can experience a second state (e.g., a high state), as illustrated by element 308 of FIG. 3. The second state indicates that the memory device is unoccupied (e.g., the memory device is not currently executing a read and/or write operation).

At operation 212, the processing logic can perform the second operation (e.g., OP 2) to determine a target erase voltage distribution of the cells associated with the block. The target erase voltage distribution can include target voltage levels that the cells associated with the block experience in an unwritten state (e.g., when the data associated with the cells is erased).

In one embodiment, the write module 113 can perform operation 214 concurrently (i.e., at least partially overlapping in time) with the local media controller 135 performing operation 216. At operation 214, the processing logic (e.g., the write module 113) can load the data to be written to a page of the block into the cache memory of the memory device, such as cache 136 of memory device 130. In some instances, the data to be written to a page of the block can be loaded into the cache memory of the memory device via a plurality of planes. In some instances, the memory device to which the data is to be written can include multiple portions. For example, the memory device can include one or more portions where sub-blocks are configured as single-level cell (SLC) memory, one or more portions where the sub-blocks are configured as multi-level cell (MLC) memory, one or more portions where the sub-blocks are configured as triple-level cell (TLC) memory, and/or one or more portions where the sub-blocks are configured as quad-level cell (QLC) memory. In some instances, the SLC portion of the memory device can be a cache memory portion of the memory device, such as cache 136 of memory device 130. The capacity of the cache memory portion of the memory device can be a fraction of the available capacity of the memory device since the SLC portion is less dense than other multi-level cell portions of memory.

The data to be written to a page of the block can be loaded into the cache memory of the memory device. As described below, upon completion of the erase algorithm, the control logic (e.g., the local media controller 135) can program the data from the cache memory portion of the memory device to a page of the block. Loading the data to the cache memory portion of the memory device (e.g., operation 306) can reduce the latency associated with executing the subsequent write command. As illustrated in FIG. 3, the data to be written to a first page of the block (e.g., PG_0) can be loaded into the cache memory via a plurality of planes 306.

At operation 216, the control logic (e.g., the local media controller 135) can determine a voltage level that is held by each cell that is associated with the block. In some instances, the processing device can perform a sense read on each cell associated with the block to determine the voltage level held therein. Based on the voltage level of each cell, the processing device can determine a voltage level distribution of the cells associated with the block. A first portion of cells can hold a high voltage level and therefore be associated with a high voltage level portion of the voltage level distribution. Alternatively, a second portion of the cells can hold a low voltage level and therefore be associated with a low voltage level portion of the voltage level distribution. For each cell that is associated with the low voltage level portion of the voltage level distribution, the processing device can adjust the voltage level of the cell. Specifically, the processing device can increase the voltage level held by the cell such that the cell experiences the high voltage level portion of the voltage level distribution (i.e., compact the voltage levels of the cells by pushing the cells associated with the low voltage portion of the voltage level distribution toward the high voltage portion of the voltage level distribution).

At operation 218, the processing logic can apply an erase voltage level (e.g., VERA) to the cells associated with the block.

At operation 220, the processing device can determine an updated voltage level distribution of the cells associated with the block after the erase voltage level is applied to the cells. Based on the updated voltage level distribution, the processing device can identify cells that are associated with a low voltage level portion of the updated voltage level distribution and a high voltage level portion of the updated voltage level distribution. Based on determining the updated voltage level distribution, the processing device can initiate the third operation (e.g., OP 3).

At operation 222, the processing device can perform the third operation (e.g., OP 3) based on the analysis conducted during the second operation (e.g., OP 2). The processing logic can compare the updated voltage level distribution to the target erase voltage distribution to perform an erase verify (e.g., EV) operation on the cells associated with the block. The processing device can determine whether the voltage level of each cell satisfies the target erase voltage distribution. In particular, the control logic can determine, based on the voltage level of each cell, whether the cell is erased.

Based on determining that the voltage level of one or more cells does not satisfy the target erase voltage distribution (i.e., one or more cells were not erased during execution of the second operation), the processing logic can return to operation 218. The processing device can apply the erase voltage level to the cells and determine an updated voltage level distribution. The processing device can perform the erase verify operation on the cells to determine whether the voltage level held by each cell satisfies the target erase voltage distribution. The processing device can repeat the third operation until the voltage level of each cell associated with the block satisfies the target erase voltage distribution (i.e., until the voltage level of each cell indicates that the corresponding cell is erased).

Based on determining that the voltage levels of the cells satisfy the target erase voltage distribution (i.e., all cells associated with the block are erased), the processing logic can, at operation 224, terminate the second and third operations, thereby completing the execution of the erase algorithm. Upon completion of the erase algorithm, the control logic can execute the write command. Specifically, the processing logic can program data from the cache memory (i.e., the data to be programmed to a page of the block).

As illustrated in FIG. 3, upon completion of the plurality of operations 304 of erase algorithm 302, the status register that is associated with the block can experience a second state (e.g., a high state), as illustrated by element 310. The high state indicates that the block (i.e., a page of the block) is prepared to receive the data to be written therein. Therefore, the processing logic can program page PG_0 with the data from the cache memory, as illustrated by element 314. As page PG_0 is programmed, the status register that is associated with the memory device can return to the low state, as illustrated by element 312. The low state indicates that the memory device is occupied (e.g., data is being written to a page of the block). Further, as page PG_0 is programmed, the status register that is associated with the block can experience a first state (e.g., a low state), which can indicate that the block is occupied (e.g., data is being written to a page of the block).

Returning to FIG. 2, at operation 226, the processing logic (e.g., the write module 113) can determine whether there remains data to be written to subsequent pages of the block. Based on determining, at operation 226, that there remains data to be written to subsequent page of the block, at operation 228, the processing device can load data to be written to a subsequent page of the block into the cache memory.

As illustrated in FIG. 3, the processing logic can load data to be programmed to page PG_1 into cache memory. In some instances, the data to be programmed to page PG_1 can be loaded into cache memory via a plurality of planes, such as plurality of planes 316. When data is loaded into the cache memory, the status register that is associated with the memory device can return to the high state, as illustrated by element 318. In this context, the high state can indicate that the memory device is available to receive data to be programmed to a block therein. Additionally, when data is loaded into the cache memory, the status register that is associated with the block can return to the high state, as illustrated by element 320. In this context, the high state can indicate that the block is available (i.e., data is not currently being written to pages of the block).

When the data to be programmed to subsequent pages of the block is loaded to the cache memory, the processing logic can return to operation 224 to write the data that is loaded to cache memory to a page of the block. As illustrated in FIG. 3, when the data to be programmed to page PG_1 is loaded to the cache memory, the control logic (e.g., the local media controller 135) can program the data from the cache memory to page PG_1, as illustrated via element 322. As the data is programmed to page PG_1, the status register that is associated with the memory device can return to the low state, as illustrated by element 324. In this context, the low state can indicate that the memory device is occupied (i.e., data is being programmed to a page of a block of the memory device). Further, as the data is programmed to page PG_1, the status register that is associated with the block can return to the low state, as illustrated by element 326. In this context, the low state can indicate that the block is occupied (i.e., data is being programmed to a page of the block). When page PG_1 is programmed, the status registers that are associated with the memory device and the block can return to respective high states, as illustrated by elements 328 and 330, respectively. In this context, the respective high states indicates that the memory device, and the block specifically, are available to receive data to be stored therein. The processing logic (e.g., the write module 113) can repeat operations 224 through 228 until the totality of the data received from the host via the write command is written to block.

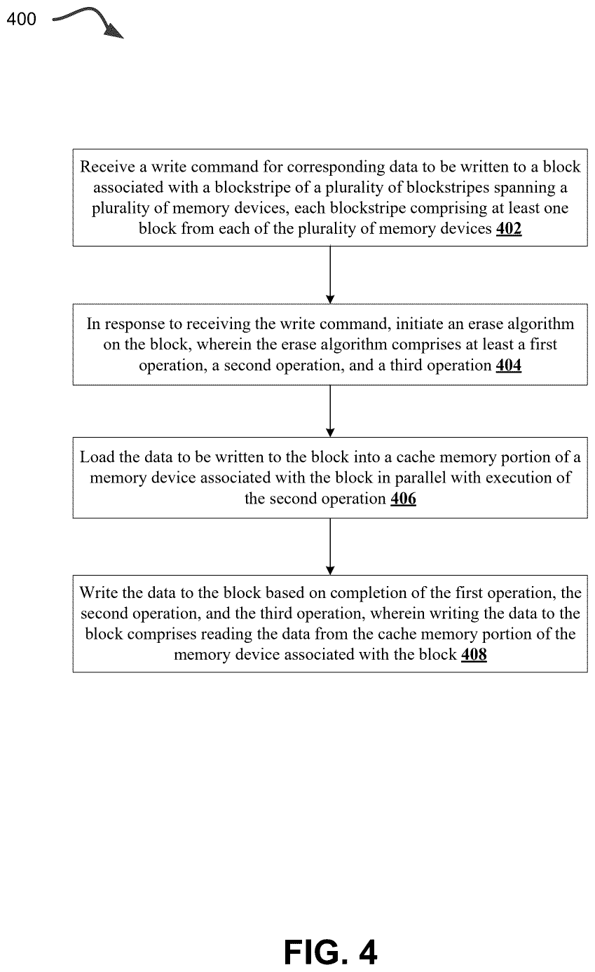

FIG. 4 illustrates an example method for implementing data caching to reduce latency associated with performing write operations on memory devices, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the write module 113 and the local media controller 135 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 402, the processing logic (e.g., the write module 113) can receive a write command for corresponding data to be written to a block. The block can be associated with a blockstripe of a plurality of blockstripes spanning a plurality of memory devices. Each blockstripe can include at least one block from each of the plurality of memory devices.

At operation 404, the processing logic (e.g., the write module 113) can, in response to receiving the write command, initiate an erase algorithm on the block if the block is not already in an erased state. The erase algorithm can include at least a first operation, a second operation, and a third operation. During the execution of the first operation, control logic of the memory device (e.g., the local media controller 135) can apply a select gate status check voltage to a select gate that controls a string of memory cells. The string of memory cells can include one or more memory cells associated with the block to which the data is to be written. Based on applying the select gate status check voltage to the select gate, the processing device can determine whether the select gate status check voltage causes the operational state of the select gate to change (e.g., to an “ON” state). Based on determining that applying the select gate status check voltage to the select gate causes the operational state of the select gate to change to the “ON” state, the processing device can terminate the first operation.

At operation 406, the processing logic (e.g., the write module 113) can load the data to be written to the block into a cache memory portion of a memory device associated with the block in parallel with execution of the second operation by the control logic (e.g., the local media controller 135). Thus, the loading and the second operation can be performed concurrently (i.e., at least partially overlapping in time). The processing device (e.g., the write module 113) can load the data to be written to the block into the cache memory portion of the memory device associated with the block in parallel with the execution of the second operation based on determining, based on the operational status of the select gate when the select gate status check voltage is applied, that the data can be written to the block. During the execution of the second operation, the control logic can determine a target erase voltage distribution of a plurality of cells associated with the block. The target erase voltage distribution can indicate a target voltage level of an erased block. During the execution of the second operation, the control logic (e.g., the local media controller 135) can adjust a voltage level distribution of a plurality of cells associated with the block. A first portion of cells of the plurality of cells can be associated with a low voltage level and a second portion of cells of the plurality of cells can be associated with a high voltage level. The processing logic can increase a voltage level of the first portion of cells of the plurality of cells from a low voltage portion of the voltage level distribution to a high voltage portion of the voltage level distribution.

During the execution of the third operation, the processing logic can apply an erase voltage level to the block. Responsive to applying the erase voltage level to the block, the processing device can determine a second voltage level distribution of the plurality of cells associated with the block. The processing device can determine whether the second voltage level distribution matches a target erase voltage distribution. Based on determining that the second voltage level distribution does not match the target erase voltage distribution, the processing device can repeat the third operation with higher erase voltage until the erase verify passes.

At operation 408, the processing logic can write the data to the block based on completion of the first operation, the second operation, and the third operation. The processing device can write the data from the cache memory portion of the memory device associated with the block.

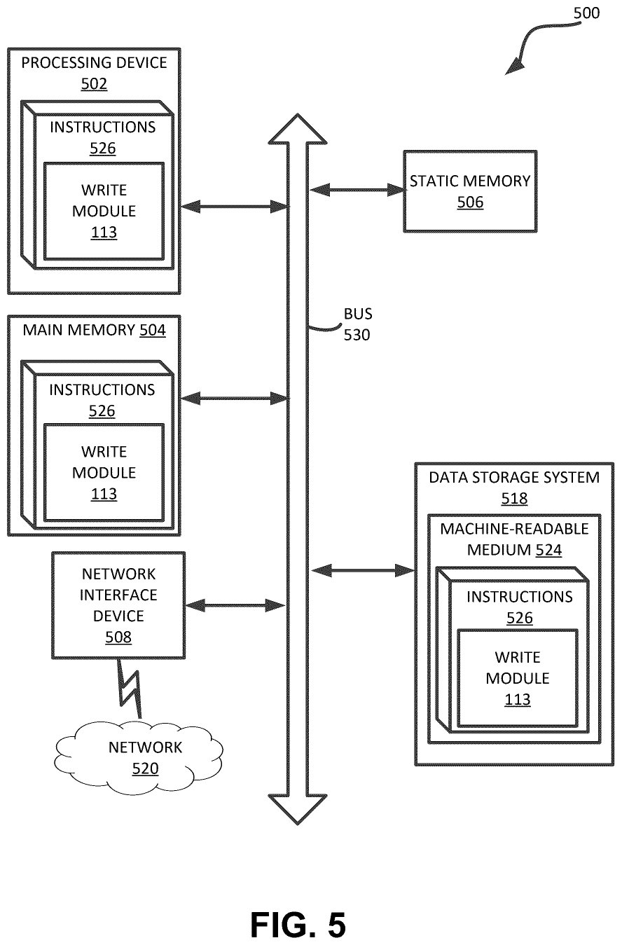

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the write module 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 can include a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which can communicate with each other via a bus 530.

Processing device 502 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 can be configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 can include instructions to implement functionality corresponding to a write module (e.g., the write module 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, which can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a plurality of memory devices; and
a processing device operatively coupled to the plurality of memory devices to perform operations comprising:
receiving a write command for corresponding data to be written to a block associated with a blockstripe of a plurality of blockstripes spanning the plurality of memory devices, each blockstripe comprising at least one block from each of the plurality of memory devices;
in response to receiving the write command, sending an erase command to a memory device associated with the block, the erase command to cause control logic of the memory device to initiate an erase algorithm on the block, wherein the erase algorithm comprises at least a first operation, a second operation, and a third operation performed by the control logic of the memory device;
loading the data to be written to the block into a cache memory portion of the memory device associated with the block in parallel with execution of the second operation by the control logic of the memory device; and
writing the data to the block based on completion of the first operation, the second operation, and the third operation, wherein writing the data to the block comprises reading the data from the cache memory portion of the memory device associated with the block.

2. The system of claim 1, wherein to perform the first operation, the control logic of the memory device is to:
apply a select gate status check voltage to a select gate that controls a string of memory cells associated with the memory device to determine, based on an operational status of the select gate, whether the data can be written to the block.

3. The system of claim 2, wherein loading the data to be written to the block into the cache memory portion of the memory device associated with the block in parallel with the execution of the second operation causes the processing device to perform operations further comprising:
determining, based on the operational status of the select gate when the select gate status check voltage is applied, that the data can be written to the block.

4. The system of claim 1, wherein to perform the second operation, the control logic of the memory device is to:
determine a target erase voltage distribution of a plurality of cells associated with the block.

5. The system of claim 4, wherein the target erase voltage distribution indicates a target voltage level of an erased block.

6. The system of claim 1, wherein to perform the second operation, the control logic of the memory device is to:
adjust a voltage level distribution of a plurality of cells associated with the block, wherein a first portion of cells of the plurality of cells are associated with a low voltage level and a second portion of cells of the plurality of cells are associated with a high voltage level.

7. The system of claim 6, wherein to adjust the voltage level distribution of the plurality of cells associated with the block, the control logic of the memory device is to:
increase a voltage level of the first portion of cells of the plurality of cells from a low voltage portion of the voltage level distribution to a high voltage portion of the voltage level distribution.

8. The system of claim 7, wherein to perform the third operation, the control logic of the memory device is to:
apply an erase voltage level to the block; and
responsive to applying the erase voltage level to the block, determine a second voltage level distribution of the plurality of cells associated with the block.

9. The system of claim 8, wherein to perform the third operation, the control logic of the memory device is to:
determine whether the second voltage level distribution matches a target erase voltage distribution.

10. The system of claim 9, wherein, based on determining that the second voltage level distribution does not match the target erase voltage distribution, the processing device performs operations further comprising:
applying the erase voltage level to the block;
determining a third voltage level distribution of the plurality of cells associated with the block; and
determining whether the third voltage level distribution matches the target erase voltage distribution.

11. The system of claim 9, wherein the data is written to the block based on determining that the second voltage level distribution matches the target erase voltage distribution.

12. A method comprising:
receiving a write command for corresponding data to be written to a block associated with a blockstripe of a plurality of blockstripes spanning a plurality of memory devices, each blockstripe comprising at least one block from each of the plurality of memory devices;
in response to receiving the write command, sending an erase command to a memory device associated with the block, the erase command to cause control logic of the memory device to initiate an erase algorithm on the block, wherein the erase algorithm comprises at least a first operation, a second operation, and a third operation performed by the control logic of the memory device;
loading the data to be written to the block into a cache memory portion of the memory device associated with the block in parallel with execution of the second operation by the control logic of the memory device; and
writing the data to the block based on completion of the first operation, the second operation, and the third operation, wherein writing the data to the block comprises reading the data from the cache memory portion of the memory device associated with the block.

13. The method of claim 12, further comprising determining a target erase voltage distribution of a plurality of cells associated with the block, wherein the target erase voltage distribution indicates a target voltage level of an erased block.

14. The method of claim 12, wherein to perform the second operation, the control logic of the memory device is to adjust a voltage level distribution of a plurality of cells associated with the block, wherein a first portion of cells of the plurality of cells are associated with a low voltage level and a second portion of cells of the plurality of cells are associated with a high voltage level.

15. The method of claim 14, wherein to adjust the voltage level distribution of the plurality of cells associated with the block, the control logic of the memory device is to adjust a voltage level of the first portion of cells of the plurality of cells from a low voltage portion of the voltage level distribution to a high voltage portion of the voltage level distribution.

16. The method of claim 15, wherein to perform the third operation, the control logic of the memory device is to:
apply an erase voltage level to the block;
responsive to applying the erase voltage level to the block, determine a second voltage level distribution of the plurality of cells associated with the block; and
determine whether the second voltage level distribution matches a target erase voltage distribution.

17. The method of claim 16, further comprising, based on determining that the second voltage level distribution does not match the target erase voltage distribution:
applying the erase voltage level to the block;
determining a third voltage level distribution of the plurality of cells associated with the block; and
determining whether the third voltage level distribution matches the target erase voltage distribution.

18. The method of claim 16, wherein the data is written to the block based on determining that the second voltage level distribution matches the target erase voltage distribution.

19. The method of claim 12, wherein to perform the first operation, the control logic of the memory device is further to:
apply a select gate status check voltage to a select gate that controls a string of memory cells associated with the memory device to determine, based on an operational status of the select gate, whether the data can be written to the block.

20. A non-transitory computer readable storage medium comprising instructions that, when executed by a processing device coupled to a plurality of memory devices, cause the processing device to perform operations comprising:
receiving a write command for corresponding data to be written to a block associated with a blockstripe of a plurality of blockstripes spanning a plurality of memory devices, each blockstripe comprising at least one block from each of the plurality of memory devices;
in response to receiving the write command, sending an erase command to a memory device associated with the block, the erase command to cause control logic of the memory device to initiate an erase algorithm on the block, wherein the erase algorithm comprises at least a first operation, a second operation, and a third operation performed by the control logic of the memory device;
loading the data to be written to the block into a cache memory portion of the memory device associated with the block in parallel with execution of the second operation by the control logic of the memory device; and
writing the data to the block based on completion of the first operation, the second operation, and the third operation, wherein writing the data to the block comprises reading the data from the cache memory portion of the memory device associated with the block.
